(19) United States
(12) Patent Application Publication
(10) Pub. No.: US 2009/0237893 A1
(43) Pub. Date: Sep. 24, 2009

(54) FIXING STRUCTURE FOR FIXING A CIRCUIT BOARD

(76) Inventor: Chun-Fei Yang, Taipei Hsien (TW)

Correspondence Address: NORTH AMERICA INTELLECTUAL PROPERTY CORPORATION, P.O. BOX 506, MERRIFIELD, VA, 22116, US

(21) Appl. No.: 12/185,797

(22) Filed: Aug. 4, 2008

(30) Foreign Application Priority Data
Mar. 24, 2008 (TW) 097205001

(51) Int. Cl. H05K 1/18

(52) U.S. Cl. 361/748

(57) ABSTRACT

A fixing structure includes a first case whereon a first boss is disposed, a circuit board whereon a hole is disposed in a position corresponding to the first boss, a fixing component for screwing in the first boss of the first case so as to fix the circuit board above the first case, a first elastic component disposed on a first side of the circuit board for supporting the circuit board above the first case, and a second elastic component disposed on a second side opposite to the first side of the circuit board for clamping the circuit board with the first elastic component.

### BACKGROUND OF THE INVENTION

1. Field of the Invention

The present invention relates to a fixing structure for fixing a circuit board, and more particularly, to a fixing structure with elastic components for clamping a circuit board.

2. Description of the Prior Art

With the rapid development of information technology, computer systems are playing an important role in modernizing many companies, which now are widely used in practically every industry. Due to the increase in data storage density, the improvement in clock speed, and the decrease in production costs, the manufacturing of portable computers has become a mainstream business in the computer industry. In general, the computer system includes a case for covering and protecting internal components. Sometimes a circuit board, such as a motherboard, is screwed to a boss of the case. However, because the circuit board is not screwed in equilibrium due to mechanical tolerance, the circuit board is not level so as to induce plane stress. It might cause local fracture due to stress concentration, and electronic components on the circuit board are brittle when an impact is applied to the circuit board.

### SUMMARY OF THE INVENTION

It is therefore a primary objective of the invention to provide a fixing structure with elastic components for clamping a circuit board for solving the above-mentioned problem.

According to the claimed invention, a fixing structure includes a first case whereon a first boss is disposed, a circuit board whereon a hole is disposed in a position corresponding to the first boss, a fixing component for screwing in the first boss of the first case so as to fix the circuit board above the first case, a first elastic component disposed on a first side of the circuit board for supporting the circuit board above the first case, and a second elastic component disposed on a second side opposite to the first side of the circuit board for clamping the circuit board with the first elastic component.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic drawing of an electronic device according to a preferred embodiment of the present invention.

FIG. 2 is a sectional view of a fixing structure of the electronic device according to the first embodiment of the present invention.

FIG. 3 is a schematic drawing of a first elastic component around a first boss according to the first embodiment of the present invention.

FIG. 4 and FIG. 5 are sectional views of a fixing structure of the electronic device according to a second embodiment of the present invention.

FIG. 6 is a sectional view of the first elastic component and a second elastic component connected to a circuit board according to the second embodiment of the present invention.

FIG. 7 is a sectional view of a fixing structure of the electronic device according to a third embodiment of the present invention.

FIG. 8 and FIG. 9 are sectional views of a fixing structure of the electronic device according to a fourth embodiment of the present invention.

### DETAILED DESCRIPTION

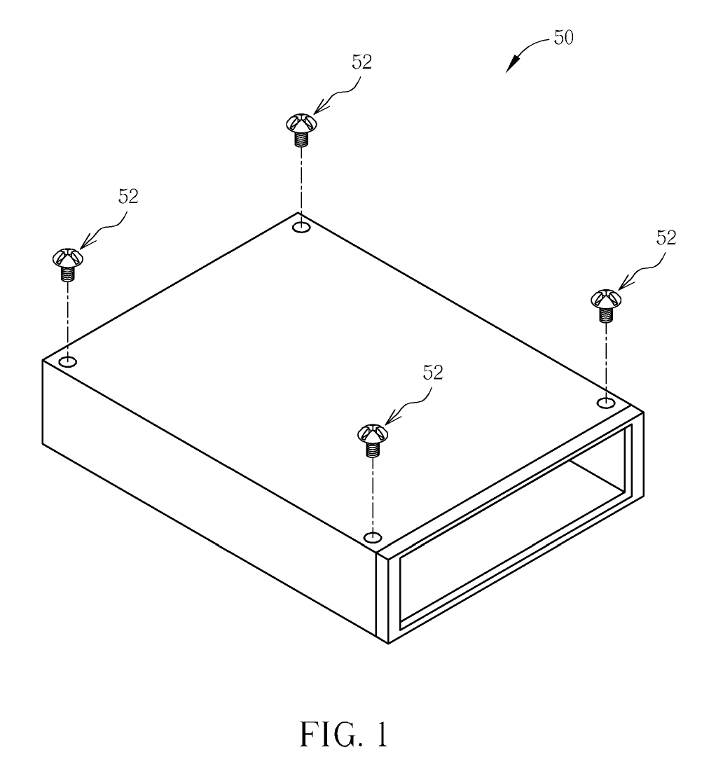

Please refer to FIG. 1, FIG. 1 is a schematic drawing of an electronic device 50 according to a preferred embodiment of the present invention. The electronic device 50 can be a computer device or a peripheral device, such as a storage device (hard disk drive, an optical disk drive, etc.), and so on. The electronic device 50 includes at least one fixing component 52 for screwing an outer case or internal components. The fixing component 52 can be a screw, and the number and the disposition of the fixing component 52 can depend on design demand.

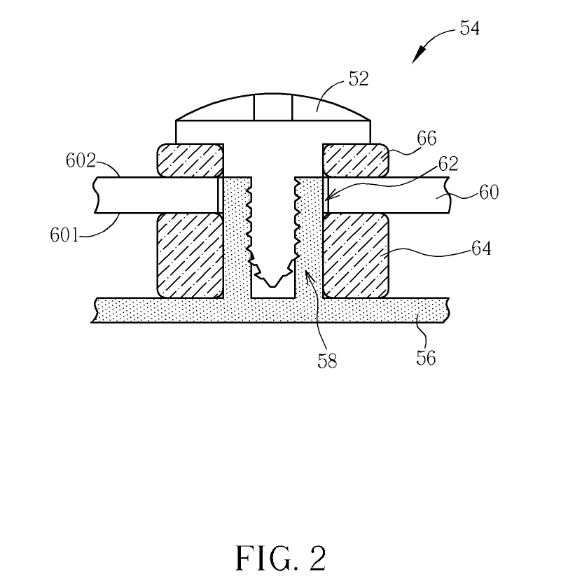

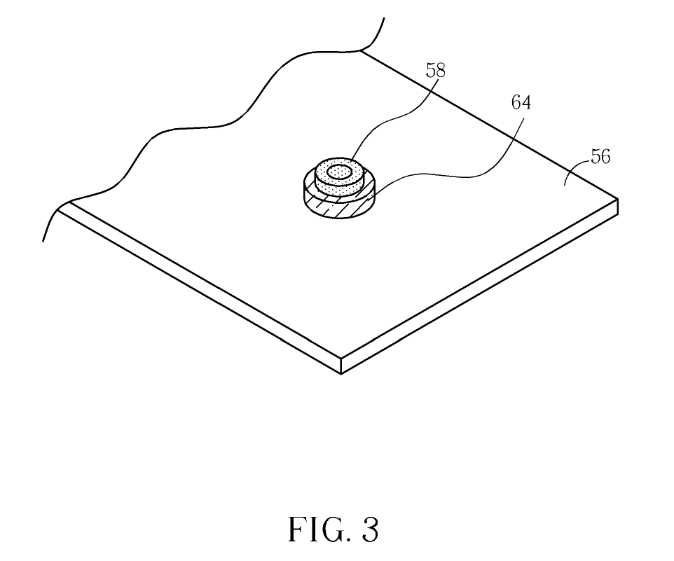

Please refer to FIG. 2, FIG. 2 is a sectional view of a fixing structure 54 of the electronic device 50 according to the first embodiment of the present invention. The fixing structure 54 includes a first case 56 which can be a lower case of the electronic device 50. At least one first boss 58 is disposed on the first case 56. The fixing structure 54 further includes a circuit board 60 which can be a printed circuit board, a motherboard, and so on. At least one hole 62 is disposed on the circuit board 60 and located in a position corresponding to the first boss 58. The fixing component 52 can be screwed in the first boss 58 on the first case 56 so as to fix the circuit board 60 above the first case 56. The fixing structure 54 further includes a first elastic component 64 disposed on a first side 601 of the circuit board 60 for supporting the circuit board 60 above the first case 56. The first elastic component 64 can be connected to the first boss 58. For example, the first elastic component 64 can be a washer around the first boss 58. Please refer to FIG. 3, FIG. 3 is a schematic drawing of the first elastic component 64 around the first boss 58 according to the first embodiment of the present invention. The first elastic component 64 can be made of rubber or can be a spring as a cushion to the circuit board 60. The first elastic component 64 can be made of conductive material, such as conductive rubber, for ground connection. The fixing structure 54 further includes a second elastic component 66 disposed on a second side 602 opposite to the first side 601 of the circuit board 60 for clamping the circuit board 60 with the first elastic component 64. The second elastic component 66 can be connected to the fixing component 52. For example, the second elastic component 66 can be a washer disposed between a head of the fixing component 52 and the circuit board 60. The second elastic component 66 can be made of rubber or can be a spring as a cushion to the circuit board 60. The second elastic component 66 can be made of conductive material, such as conductive rubber, for ground connection.

The first elastic component 64 and the second elastic component 66 clamp the circuit board 60 together so that the first side 601 and the second side 602 of the circuit board 60 don't contact with rigid structure directly. Hence the circuit board 60 is capable of displacing up and down slightly as a suspension mechanism due to the cushion provided by the first elastic component 64 and the second elastic component 66. When there is a plurality of the fixing components 52 for screwing the circuit board 60, the first elastic components 64 and the second elastic components 66 for the plurality of the fixing components 52 clamp the circuit board 60 together so as to overcome tolerance of unbalanced screwing force of the plurality of the fixing components 52 and keep the circuit board 60 plane.

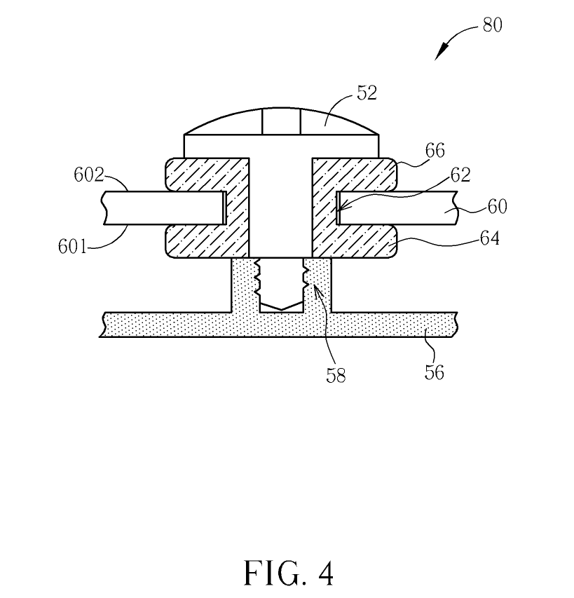

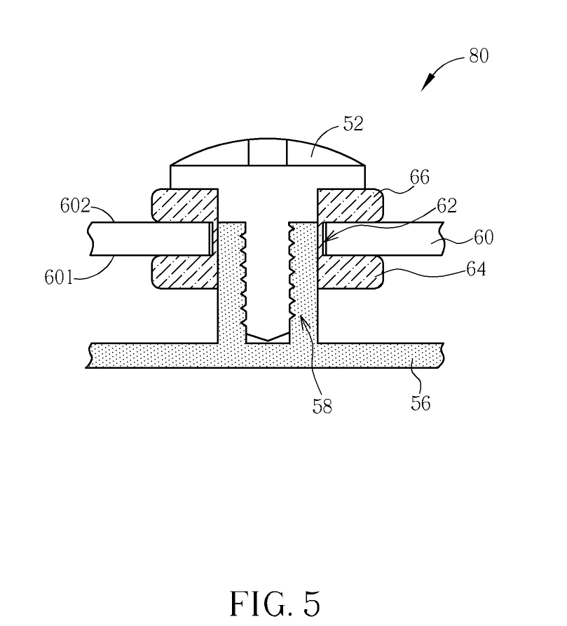

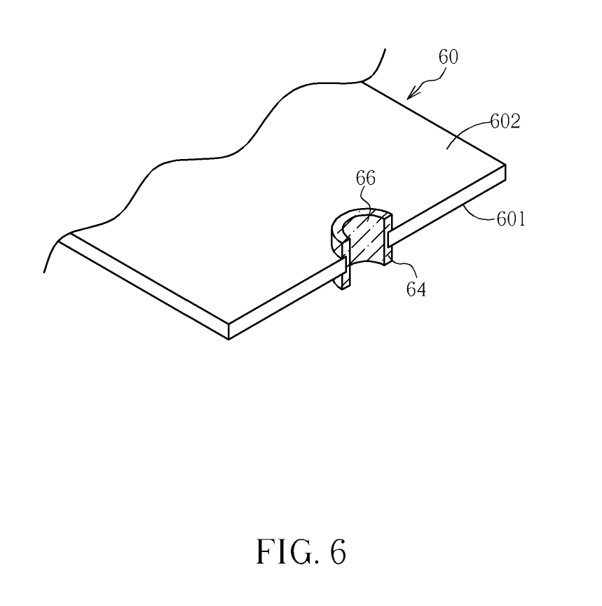

Please refer to FIG. 4 and FIG. 5, FIG. 4 and FIG. 5 are sectional views of a fixing structure 80 of the electronic device 50 according to a second embodiment of the present invention. The difference between the first embodiment and the second embodiment is that the first elastic component 64 and the second elastic component 66 are connected integrally. The first elastic component 64 and the second elastic component 66 can be formed as a washer for sheathing the fixing component 52. The first elastic component 64 and the second elastic component 66 can be integrated with the circuit board 60 directly. Please refer to FIG. 6, FIG. 6 is a sectional view of the first elastic component 64 and the second elastic component 66 connected to the circuit board 60 according to the second embodiment of the present invention. The first elastic component 64 and the second elastic component 66 are formed as the washer for inserting into the hole 62 on the circuit board 60. As shown in FIG. 4, then the fixing component 52 passes through the first elastic component 64 and the second elastic component 66 and is screwed in the first boss 58 on the first case 56. Or as shown in FIG. 5, the first boss 58 on the first case 56 passes through the first elastic component 64 and the second elastic component 66, and the fixing component 52 is screwed in the first boss 58. Similarly, the first elastic component 64 and the second elastic component 66 clamp the circuit board 60 together so that the first side 601 and the second side 602 of the circuit board 60 don't contact with rigid structure directly. Hence the circuit board 60 is capable of displacing up and down slightly as a suspension mechanism due to the cushion provided by the first elastic component 64 and the second elastic component 66 so as to overcome tolerance of unbalanced screwing force of the plurality of the fixing components 52 and keep the circuit board 60 plane.

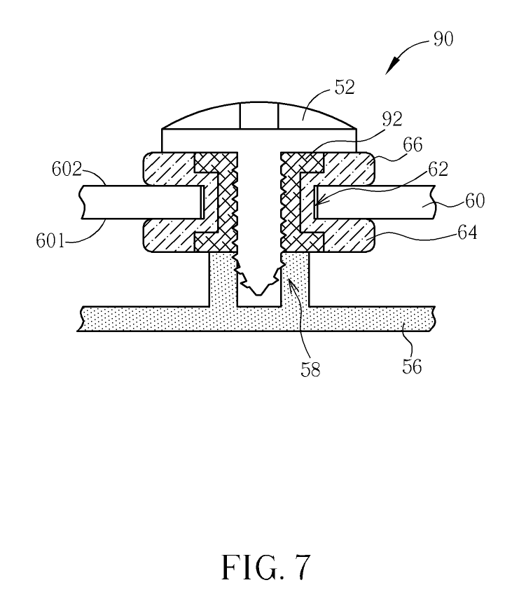

Please refer to FIG. 7, FIG. 7 is a sectional views of a fixing structure 90 of the electronic device 50 according to a third embodiment of the present invention. The difference between the second embodiment and the third embodiment is that the fixing structure 90 further includes a rigid washer 92 disposed inside the washer formed by the first elastic component 64 and the second elastic component 66 for sheathing the fixing component 52. The rigid washer 92 is made of rigid material, such as plastic or metal material. The rigid washer 92 and the washer formed by the first elastic component 64 and the second elastic component 66 can be integrated with double injection method. The rigid washer 92 and the washer formed by the first elastic component 64 and the second elastic component 66 can be inserted into the hole 62 on the circuit board 60, and then the fixing component 52 passes through the rigid washer 92 and is screwed in the rigid washer 92 and the first boss 58 on the first case 56. The rigid washer 92 can strengthen the fixing effect of the fixing component 52 and can prevent the first elastic component 64 and the second elastic component 66 from wear. Similarly, the first elastic component 64 and the second elastic component 66 clamp the circuit board 60 together so that the first side 601 and the second side 602 of the circuit board 60 don't contact with rigid structure directly. Hence the circuit board 60 is capable of displacing up and down slightly as a suspension mechanism due to the cushion provided by the first elastic component 64 and the second elastic component 66 so as to overcome tolerance of unbalanced screwing force of the plurality of the fixing components 52 and keep the circuit board 60 plane.

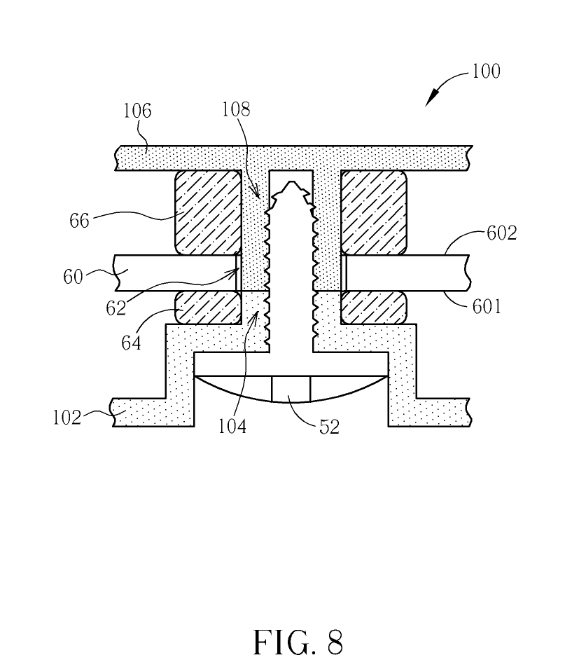

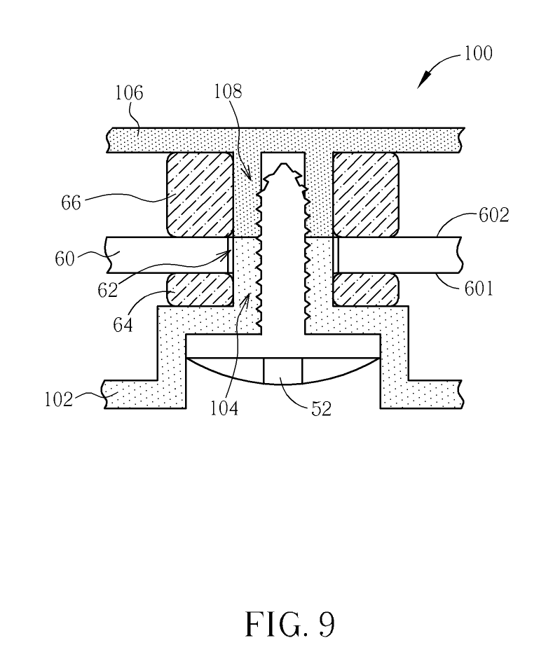

Please refer FIG. 8 and FIG. 8, FIG. 8 and FIG. 9 are sectional views of a fixing structure 100 of the electronic device 50 according to a fourth embodiment of the present invention. As shown in FIG. 8, the fixing structure 100 includes a first case 102 which can be a lower case of the electronic device 50. At least one first boss 104 is disposed on the first case 102. The fixing structure 100 further includes a second case 106 which can be an upper case of the electronic device 50 for covering internal components of the electronic device 50. At least one second boss 108 is disposed on the second case 106 and located in a position corresponding to the first boss 104 for passing through the hole 62 on the circuit board 60. The second boss 108 on the second case 106 is assembled with the circuit board 60, and then the first case 102 is assembled with the second case 106 and the circuit board 60. Besides, as shown in FIG. 9, the first boss 104 passes through the hole 62 on the circuit board 60. The first boss 104 on the first case 102 is assembled with the circuit board 60, and then the second case 106 is assembled with the first case 102 and the circuit board 60. The fixing component 52 passes through the first boss 104 on the first case 102 and the second boss 108 on the second case 106 so as to fix the circuit board 60 between the first case 102 and the second case 106. Similarly, the first elastic component 64 disposed on the first side 601 of the circuit board 60 for supporting the circuit board 60 above the first boss 104. The first elastic component 64 can be connected to the first boss 104. For example, the first elastic component 64 can be a washer around the first boss 104. The second elastic component 66 disposed on the second side 602 opposite to the first side 601 of the circuit board 60 for clamping the circuit board 60 with the first elastic component 64. The second elastic component 66 can be connected to the second boss 108. For example, the second elastic component 66 can be a washer around the second boss 108. Similarly, the first elastic component 64 and the second elastic component 66 clamp the circuit board 60 together so that the first side 601 and the second side 602 of the circuit board 60 don't contact with rigid structure directly. Hence the circuit board 60 is capable of displacing up and down slightly as a suspension mechanism due to the cushion provided by the first elastic component 64 and the second elastic component 66 so as to overcome tolerance of unbalanced screwing force of the plurality of the fixing components 52 and keep the circuit board 60 plane.

In conclusion, the fixing structure of the present invention utilizes elastic components to clamp an upper side and a lower side of the circuit board so that the upper side and the lower side of the circuit board don't contact with rigid structure directly. Hence the circuit board is capable of displacing up and down slightly as a suspension mechanism due to the cushion provided by the elastic components so as to overcome tolerance of unbalanced screwing force of the plurality of the fixing components and keep the circuit board plane. The structure for preventing the circuit board from contacting with rigid structure directly is within the scope of the present invention.

In contrast to the prior art, the fixing structure of the present invention utilizes elastic components to clamp the circuit board so that the circuit board don't contact with rigid structure directly. The circuit board is capable of displacing up and down slightly as a suspension mechanism due to the cushion provided by the elastic components so as to overcome tolerance of unbalanced screwing force of the plurality of the fixing components and keep the circuit board plane.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A fixing structure comprising:
a first case whereon a first boss is disposed;
a circuit board whereon a hole is disposed in a position corresponding to the first boss;
a fixing component for screwing in the first boss of the first case so as to fix the circuit board above the first case;
a first elastic component disposed on a first side of the circuit board for supporting the circuit board above the first case; and
a second elastic component disposed on a second side opposite to the first side of the circuit board for clamping the circuit board with the first elastic component.

2. The fixing structure of claim 1 wherein the fixing component is a screw.

3. The fixing structure of claim 1 wherein the first elastic component is connected to the first boss.

4. The fixing structure of claim 3 wherein the second elastic component is connected to the fixing component.

5. The fixing structure of claim 1 wherein the second elastic component is connected to the fixing component.

6. The fixing structure of claim 1 wherein the first elastic component and the second elastic component are connected integrally.

7. The fixing structure of claim 6 wherein the first elastic component and the second elastic component are formed as a washer for sheathing the fixing component.

8. The fixing structure of claim 6 wherein the first elastic component and the second elastic component are connected to the circuit board.

9. The fixing structure of claim 6 further comprising a rigid washer disposed inside the first elastic component and the second elastic component for sheathing the fixing component.

10. The fixing structure of claim 9 wherein the rigid washer is made of plastic material or metal material.

11. The fixing structure of claim 1 further comprising a second case whereon a second boss is disposed, and the fixing component passing through the first boss of the first case and the second boss of the second case so as to fix the circuit board between the first case and the second case.

12. The fixing structure of claim 11 wherein the first elastic component is connected to the first boss.

13. The fixing structure of claim 11 wherein the second elastic component is connected to the second boss.

14. The fixing structure of claim 1 wherein the first elastic component is made of rubber.

15. The fixing structure of claim 1 wherein the first elastic component is a spring.

16. The fixing structure of claim 1 wherein the first elastic component is made of conductive material.

17. The fixing structure of claim 1 wherein the second elastic component is made of rubber.

18. The fixing structure of claim 1 wherein the second elastic component is a spring.

19. The fixing structure of claim 1 wherein the second elastic component is made of conductive material.

20. The fixing structure of claim 1 wherein the circuit board is a motherboard.
